(19) United States
(12) Patent Application Publication
(10) Pub. No.: US 2001/0052625 A1
(43) Pub. Date: Dec. 20, 2001

(54) Semiconductor memory device and manufacturing method therefor

(75) Inventor: Kazuhiko Sanada, Tokyo (JP)

Correspondence Address: Attention: Norman P. Soloway, HAYES, SOLOWAY, HENNESSEY,, GROSSMAN & HAGE, P.C., 175 Canal Street, Manchester, NH, 03101, US

(73) Assignee: NEC Corporation

(21) Appl. No.: 09/883,702

(22) Filed: Jun. 18, 2001

(30) Foreign Application Priority Data
Jun. 19, 2000 (JP) 2000-182498

(51) Int. Cl. H01L 21/8234; H01L 21/336; H01L 29/94; H01L 29/76

(52) U.S. Cl. 257/390; 438/275; 438/279

(57) ABSTRACT

A manufacturing method for a semiconductor memory device is provided, which comprises the steps of forming buried layers 2 for bit lines, forming gate electrodes 3 which cross the buried layers 2 at a right angle, and depositing an interlayer insulating film 5 (C). Ion injection windows are opened through the interlayer insulating film on the channel regions of every memory cell using a regular reticule pattern (D). A photoresist film 7 in conformity with the code pattern is formed and ion injected layer 8 is formed at a prescribed channel region for writing information. It becomes possible to form the ion injection windows without being affected by the density of the code pattern and to inject ions at low energy. Therefore, the transverse broadening of the injection ion beam can be prevented, to prevent fluctuations of the threshold voltage of the non-selected cells.

### BACKGROUND OF THE INVENTION

1.Field of the Invention

The present invention relates to a semiconductor memory device and a manufacturing method therefor, and particularly relates to a method for writing data on a mask ROM.

2. Description of the Related Art

In a manufacturing process of a mask ROM having a MOS-type field effect transistor (FET) as a memory element, ion injection is carried out as a method to control the threshold voltage of the MOSFET for writing data.

FIGS. 7A to 7C are cross-sectional diagrams showing a conventional manufacturing method of a NOR-type mask ROM in the order of the manufacturing process. In the conventional manufacturing method, buried diffusion layers (not shown in the figure) for constituting bit lines are formed on a silicon substrate 101, gate electrodes 103 are formed on the silicon substrate through a gate insulating film, and an interlayer insulating film 105 is formed on the entire surface of the silicon substrate. These wafers fabricated to this stage are stored as partially fabricated products awaiting orders from customers (FIG. 7A).

When an order arrives from a customer, a photoresist film 107 is formed on the interlayer insulating film 105, and the photoresist film is exposed through a mask 10 (hereinafter, called a code reticule) for writing data in accordance with the customer's order, and, after developing the exposed photoresist film 107, ion injection windows 107a are formed; thus the resist mask is obtained (FIG. 7B). Ion injection is performed on the entire surface of the substrate through this resist mask. When impurity ions such as arsenic (As) ions enter from the ion injection windows 107a, these impurity ions pass through the interlayer insulating film 105 and the gate electrode 103 and reach channel regions between the drain regions (between the buried diffusion layers). Thereby, the ion injection layers 108 are formed and the threshold value of the cell transistor is controlled to be an optimum value, and an operation for writing data is completed (FIG. 7C).

The above-described conventional technique has the following problems.

The first problem is that, when the resist mask is formed by a lithographic method using the code reticule, the sizes of the ion injection windows formed on the resist mask varies with the region in the mask depending upon whether the ion injection windows are densely or sparsely populated in the resist mask pattern (hereinafter, called a code pattern). In detail, as shown in FIG. 8, due to diffraction and interference of light, the ion injection windows 21 in a dense region of the code pattern become larger and the ion injection windows 22 in the sparse region of the code pattern become smaller. Thus, the sizes of the ion injection windows change in both dense and coarse regions in the resist mask, which causes a problem in both the dense and sparse regions.

In the dense portion of the code pattern, since the ion injection windows are large, the margin of space for the resist mask to cover the non-selected cells becomes small, and ions are likely to be injected into a channel region of non-selected cells where ion injection must be avoided, and this causes fluctuations of the threshold voltage. In contrast, in the sparsely populated region of the code pattern, since the ion injection window is small, the amount of ions injected into the selected cells may be insufficient. It is noted, however, the non-selected cells 24 in the coarse portion are not subjected to the effects of the ion injection.

The second problem in the conventional technique is that the ion injection beam broadens in the transverse direction. In the conventional method, since data writing is performed by ions which pass through the interlayer insulating layer and the gate electrode, although it depends on the thickness of both of the interlayer insulating film and the gate electrode, the data writing must be carried out using ions having an acceleration energy of 200 to 300 KeV. Since the degree of the broadening of the ion beam is proportional to the acceleration energy of the ion beam, it is inevitable for the ion beam in the conventional technique to broaden in the transverse direction.

Since the ion injection to the non-selected cells through the broadened windows makes the threshold voltage fluctuate, this means that the broadened window reduces the margin of the coverage area by the resist mask for the non-selected cell. That is, if energy of the ion injection can be reduced, the margin of the coverage area by the resist mask can be increased and data writing can be performed in a more stable manner.

### SUMMARY OF THE INVENTION

The present invention is made for solving the above-described problems in the conventional technique and an object of the present invention is to provide a semiconductor memory device and manufacturing method thereof. The desired semiconductor memory device is capable of writing data in more stable manner without being affected by the density of ion injection windows in the code pattern, and is also capable of preventing fluctuations in the threshold voltage of the non-selected cells by suppressing transverse broadening of the injection ion beam.

According to the first aspect, the present invention provides a semiconductor memory device, which comprises a plurality of gate electrodes, a plurality of buried layers for forming bit lines which are formed crossing said gate electrodes on the surface regions of a semiconductor substrate, and an interlayer insulating film, and in which information is written by selective ion injection into channel regions formed in between said buried layers; wherein ion injection windows are formed so as to reach said gate electrode by selectively removing said interlayer insulating film on the channel regions of all memory cells and all of said ion injection windows are filled later by another insulating film.

In order to obtain the above semiconductor memory device, the present invention provides a manufacturing method which comprises the steps of (1) forming a plurality of gate electrodes on a silicon substrate though a gate insulating film, (2) depositing interlayer insulating film on the entire surface of the substrate, (3) forming ion injection windows for exposing the surface of said gate electrodes above the channel regions of every memory cell by selective etching of said interlayer insulating film, (4) forming a photoresist film having apertures selectively formed on said ion injection windows for injecting ions by a photolithographic method, and (5) forming ion injected layers on the desired channel regions by executing ion injection using said photoresist film and said interlayer insulating film as mask layers.

According to the method of writing data onto the semiconductor device of the present invention, ion injection windows are formed prior to writing data by removing the interlayer insulating film on the channels of every memory cells. In the photolithographic step for opening the windows, apertures are formed on every memory cell so that the ion injection windows can be formed in a uniform size without being affected by the density of the windows. In addition, because it becomes unnecessary to inject ions to penetrate through the interlayer insulating film, the ion injection energy can be reduced so that the transverse broadening of the ion beam can be minimized and the fluctuation of the threshold voltages of the non-selected cells can be prevented.

### BRIEF DESCRIPTION OF THE DRAWINGS

FIG. 1 is a layout diagram showing the memory cell array portion of the mask ROM according to the present invention.

FIGS. 2A and 2B are cross-sectional views (first part) of the manufacturing method according to the first embodiment of the present invention.

FIGS. 3C to 3E are cross-sectional views (second part) of the manufacturing method according to the first embodiment of the present invention.

FIGS. 4F to 4H are cross-sectional views (third part) of the manufacturing method according to the first embodiment of the present invention.

FIGS. 5A to 5C are cross sectional views (first part) of the manufacturing method according to the second embodiment of the present invention.

FIGS. 6D to 6F are cross sectional views (first part) of the manufacturing method according to the second embodiment of the present invention.

FIGS. 7A to 7C are cross sectional views showing the conventional manufacturing method.

FIG. 8 is a diagram explaining the problems of the conventional example.

### DETAILED DESCRIPTION OF THE INVENTION

Hereinafter, the present invention is described based on the first and second embodiments of the present invention with reference to the attached drawings.

FIG. 1 is a layout diagram showing the memory cell array portion of a mask ROM according to the present invention. As shown in FIG. 1, in a surface region of a silicon substrate, a plurality of buried diffusion layers 2 are formed in parallel to each other for forming bit lines, and a plurality of gate electrodes 3 are formed for forming word lines in parallel to each other on the substrate through the gate insulating layer in the direction crossing the buried diffusion layer 2. The region in the middle of two buried diffusion layers 2 under the gate electrodes 3 constitutes a channel region 4.

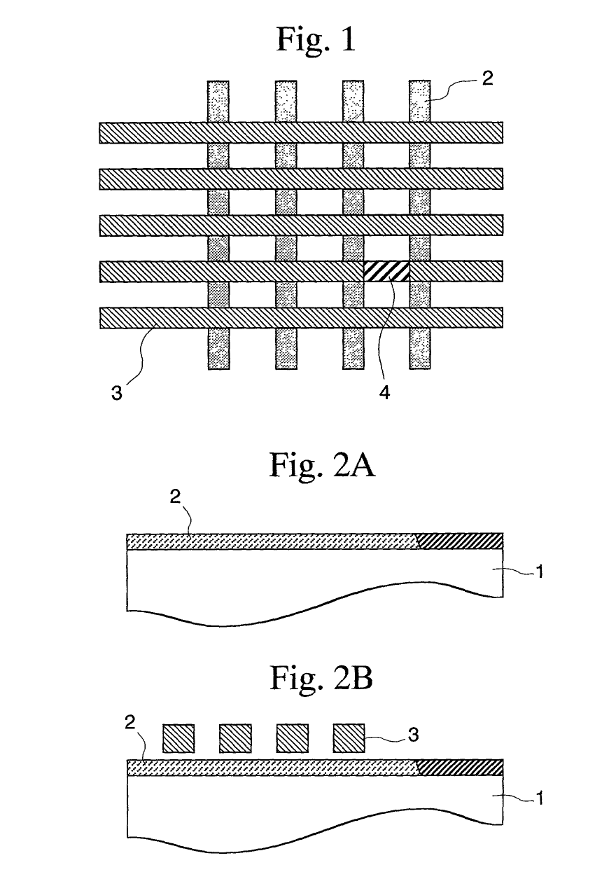

FIGS. 2A to FIG. 4 are cross-sectional views showing the manufacturing method in the manufacturing order according to the first embodiment of the present invention.

After forming a resist pattern by photolithography on a silicon substrate 1, arsenic ions are injected at an injection energy of 70 keV and at a dose of 2×10¹⁵ cm⁻². After heat treatment, a plurality of buried layers 2, which constitute bit lines, are formed in parallel to each other at a certain interval (FIG. 2A). Since these buried layers do not appear on the sheet except for the diffusion layer just beneath a contact hole, they are shown by dotted lines.

Subsequently, a gate oxide layer with a thickness of approximately 10 nm is formed, and on the oxide layer, an approximately 100 nm thick polysilicon layer doped with phosphorus (P) and an approximately 100 nm thick tungsten silicide (WSi) layer are formed and a plurality of gate electrodes crossing the buried layers 2 at a right angle are formed by patterning these layers using photolithography and dry etching (FIG. 2B).

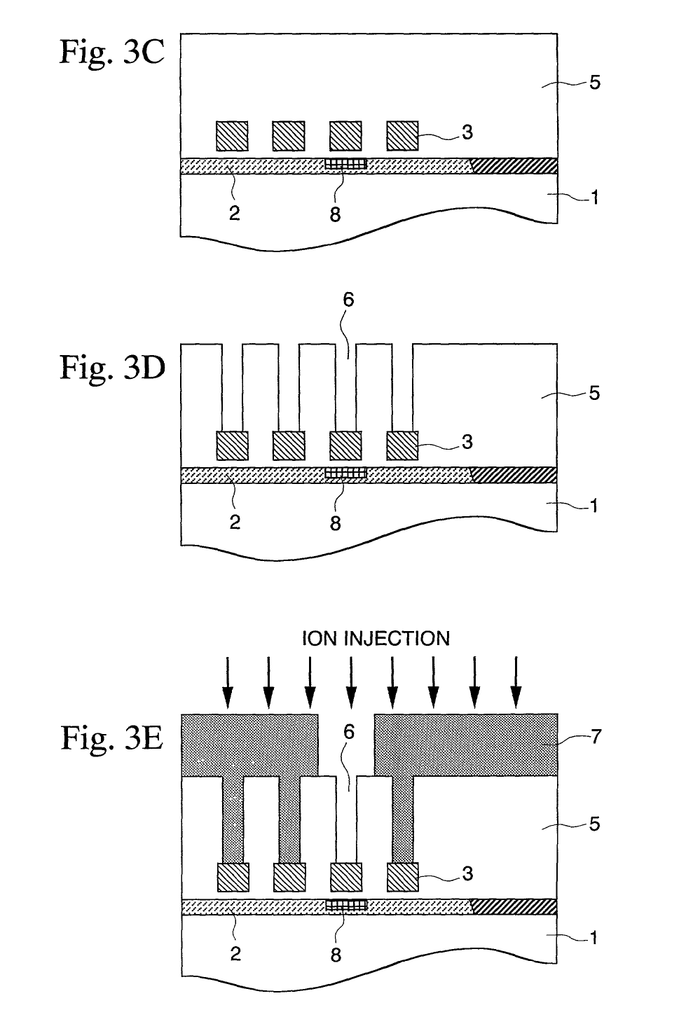

Subsequently, an interlayer insulating film 5 having a thickness of 500 to 1000 nm is deposited on an entire surface of the substrate (FIG. 3C).

Subsequently, the interlayer insulating film 5 is etched after performing photolithography using a code reticule having a uniform pattern density, and ion injection windows are formed on each channel region (see FIG. 1) of the entire memory cell area at a size of 0.18 to 0.24 μm. At the time of etching, since the tungsten silicide films of the interlayer insulating film 5 and the gate electrode 3 have a high selection ratio, the gate electrode 3 is not etched out. However, the thickness of the gate electrode may be reduced in a etching process. It is possible to prevent the etching loss by depositing a silicon film or a silicon nitride (SiN) film on the tungsten silicide film with a thickness of 50 μm. Consequently, the gate electrode can be protected from being converted to a high resistance film due to etching loss, and the ion injection windows can be formed without affecting the gate electrode portion (FIG. 3D).

Subsequently, a photoresist film 7 is formed on the entire surface of the interlayer insulating film 5 so as to fill the ion injection window, and a resist mask is formed by exposing and developing using the code reticule. Then, impurity ions are injected through ion injection windows, which are not masked by the resist mask for forming the ion injected layer 8 (FIG. 3E).

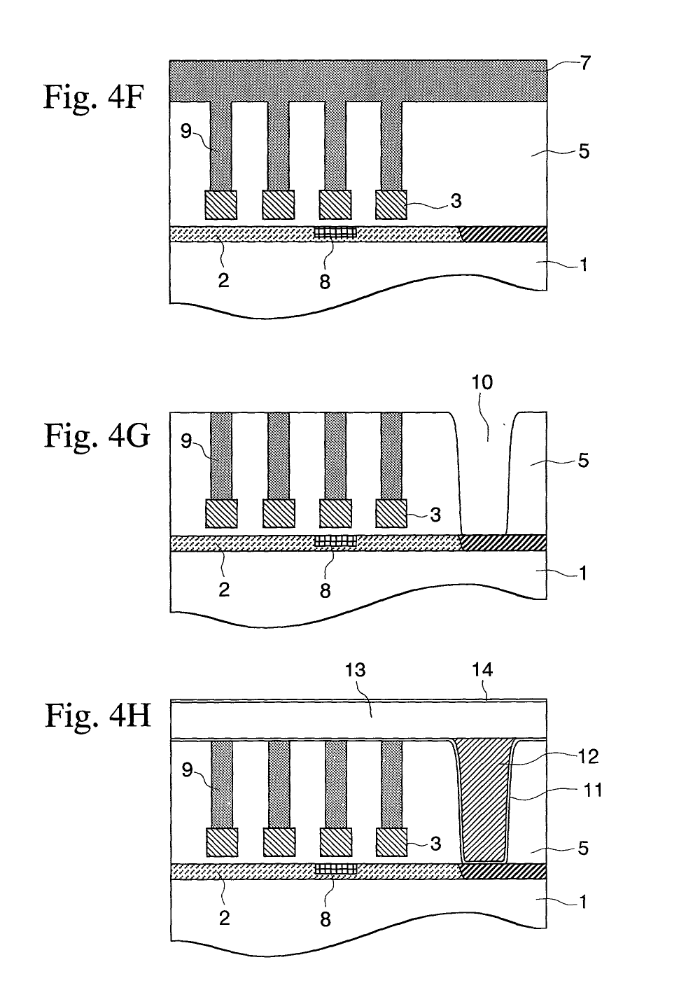

Subsequently, the photoresist film is removed by ashing, and the oxide film 9 deposited on the entire surface buries the ion injection windows 6 (FIG. 4F).

Subsequently, an etch-back process removes the unnecessary oxide film 9 and a contact hole 10 is formed by a combination of photolithography and etching (FIG. 4G).

Subsequently, a barrier metal layer 11 having a double layered structure composed of titanium (Ti) and titanium nitride (TiN) is deposited on the interlayer insulating film 5 and on an inner surface of the contact hole 10, and then the contact hole 10 is filled with a tungsten film 12 by selective growth of the tungsten (W). It is also possible, in place of the selective growth of the tungsten film, to form a tungsten plug by deposition of the blanket tungsten film and by CMP or by an etch-back process. Subsequently, an aluminum alloy film 13 and a TiN film 14 are deposited on the entire surface of the interlayer insulating film 5 and wiring is formed by patterning these layers.

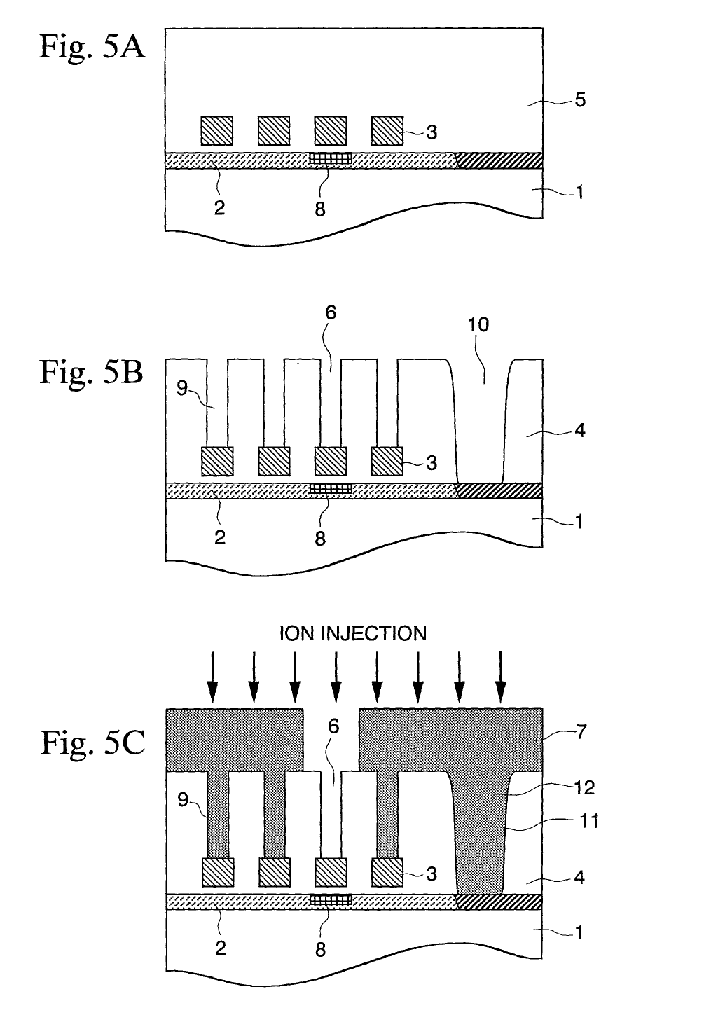

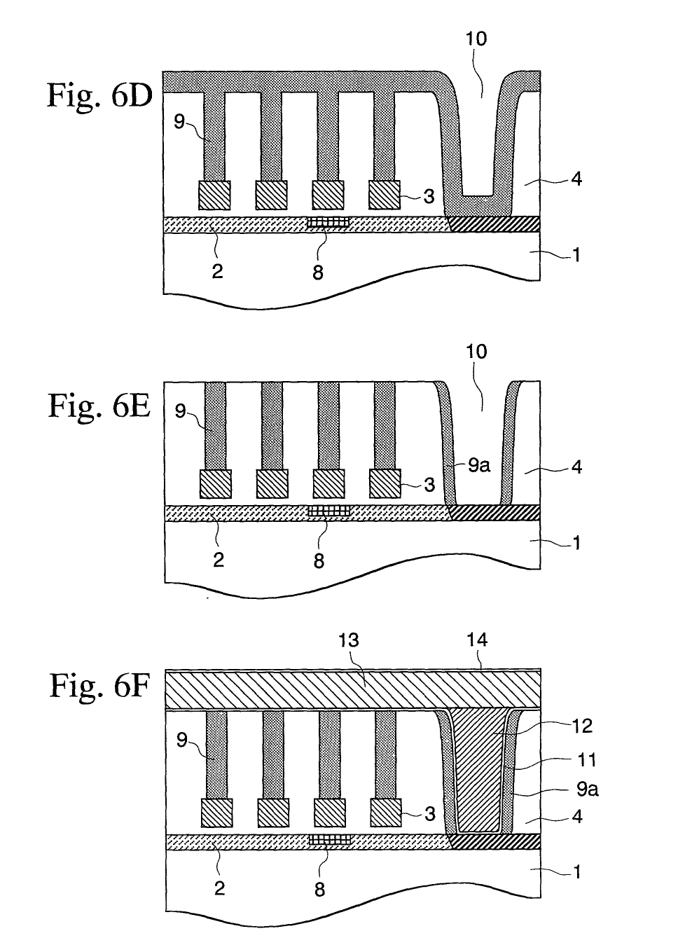

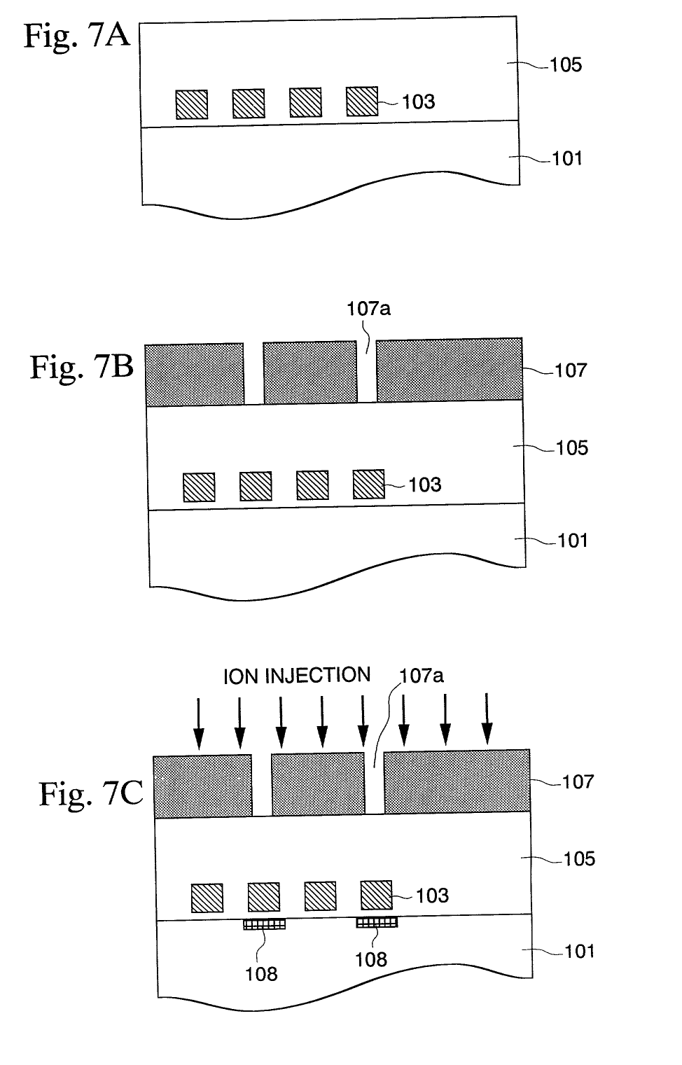

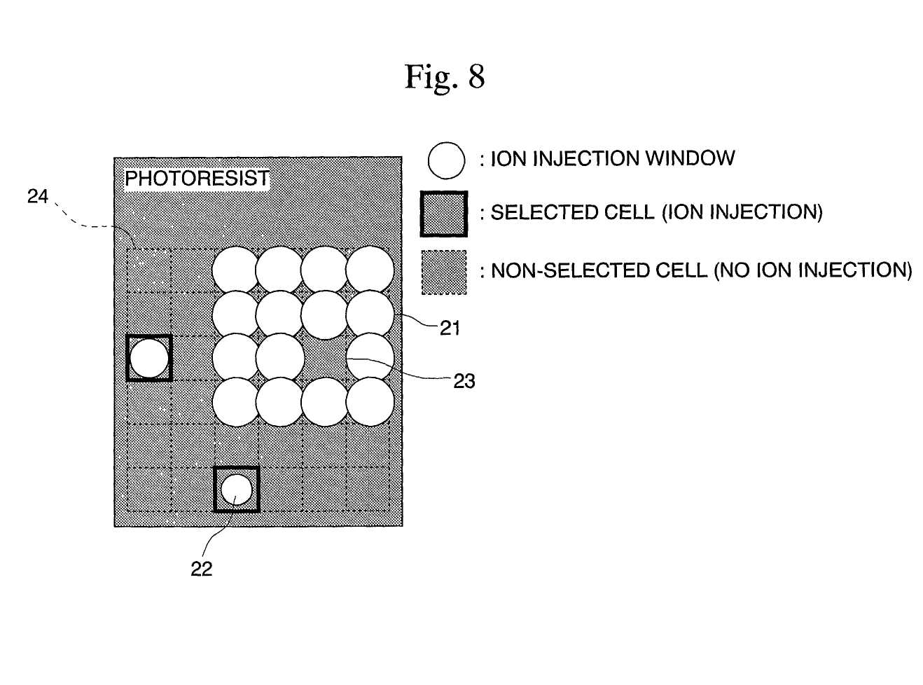

FIG. 5A to FIG. 6F are cross-sectional views showing a manufacturing process in the manufacturing order of a semiconductor device according to the second embodiment of the present invention. In FIGS. 5 and 6, the same components as those in the first embodiment shown in FIGS. 2 and 4 are denoted by the same reference numerals, and their explanations are omitted. The difference distinguishing the second embodiment from the first embodiment is that the second embodiment forms the contact hole in the same process for forming the ion injection windows 6. That is, the manufacturing processes of the second embodiment are the same as those of the first embodiment until the FIG. 3C. Thus, the manufacturing processes of the second embodiment are described after the process shown in FIG. 5A corresponding to FIG. 3C.

After forming the semiconductor device in the state shown in FIG. 5A, ion injection window 6 is formed. At the same time, the contact hole 10 is formed (FIG. 5B). The contact hole 10 is formed with a diameter, which is larger by 0.5 μm than that of the ion injection window 6. The data writing is performed by the same method as that of the first embodiment (FIG. 5C).

After writing the data, the oxide film 9 is formed with a thickness of 200 to 300 nm by CVD. Since the size of the ion injection window 6 is smaller than the contact hole 10, the oxide film 9 can fill the ion injection window 6. However, since the contact hole 10 is larger by 0.5 μm than the ion injection window 6, the contact hole cannot be filled by the oxide film 9.

Subsequently, the unnecessary oxide film is removed by the etch-back process. At this time, since the ion injection window 6 is filled completely, the oxide film filling the injection hole remains without being removed by the etch-back process. However, since the contact hole 6 is formed larger than the ion injection window 10, the oxide film in the contact hole is removed by the etch-back process and at the bottom of the contact hole, the silicon substrate surface is exposed, which can be exposed for forming a contact. The thickness of the side wall 9a remaining on the side wall of the contact hole 10 is about 0.8 times as the thickness of the original deposited film, so that when the size of the contact hole 10 is formed larger than the ion injection windows by 0.5 μm. the contact hole is not buried completely by the oxide film (FIG. 6E). Thereafter, the tungsten plug and the wiring layer are formed (FIG. 6F).

As shown above, the number of the manufacturing steps in the first embodiment is increased by the photolithography process, when compared to the number of the conventional manufacturing process. However, in the second embodiment, it is not necessary to add a photolithographic process, and the semiconductor device of the second embodiment can be produced by the addition of two simple processes of the oxide film formation and the etch-back.

As shown above, two preferable embodiments are described. However, the present invention is not limited to these embodiments and variants thereof can be envisaged which do not exceed the scope of the present invention. For instance, the ion injection can be performed immediately after formation of the ion injection windows as shown in FIGS. 3D and 5B, and the devices can be stored at the partially fabricated state before ion injection. It is preferable to cover the gate electrodes of these partially fabricated devices with a protective film. In addition, a silicon nitride film can be used in place of the silicon oxide film as the material to fill the ion injection window. Although the etch-back process is applied to the oxide film 9 in the first embodiment, this process may be omitted.

As described above, the interlayer insulating film on the channel region of all the memory cells is formed for forming ion injection windows using a reticule having a regular pattern, the size of the ion injection windows may not be affected, even if the apertures of the resist mask may be affected by the density of the code pattern, which enables the stable writing operation.

In addition, since the ion injection can be performed at a low energy, it is possible to suppress the transverse broadening of the ion injection beam and it is possible to prevent fluctuations of the threshold voltage of the non-selected cells.

What is claimed is:

1. A semiconductor memory device, which comprises a plurality of gate electrodes, a plurality of buried layers for forming bit lines which are formed crossing said gate electrodes on the surface regions of a semiconductor substrate, and an interlayer insulating film, and in which information is written by selective ion injection into a channel region formed in between said buried layers; wherein ion injection windows are formed so as to reach said gate electrode by selectively removing said interlayer insulating film on the channel regions of all memory cells and all of said ion injection windows are filled by another insulating film.

2. A semiconductor memory device according to claim 1, wherein at least a surface region of said gate electrode is formed of a material which functions as a stopper at the time of etching of said interlayer insulating film.

3. A semiconductor memory device according to claim 2, wherein the material which functions as the etching stopper is a silicide of high melting point metals.

4. A manufacturing method for a semiconductor memory device comprising the steps of:
(1) forming a plurality of gate electrodes on a silicon substrate though a gate insulating film;
(2) depositing an interlayer insulating film on the entire surface of the substrate;
(3) forming ion injection windows for exposing the surface of said gate electrodes above the channel regions of every memory cell by selective etching of said interlayer insulating film;
(4) forming a photoresist film having apertures selectively formed on said ion injection windows for injecting ions by a photolithographic method;
(5) forming ion injected layers on desired channel regions by executing ion injection using said photoresist film and said interlayer insulating film as mask layers.

5. A manufacturing method for a semiconductor memory device comprising the steps of:
(1) forming a plurality of gate electrodes by depositing and patterning a gate electrode forming material and a protection film on a silicon substrate through a gate insulating film:
(2) depositing an interlayer insulating film on a entire surface of the protection film;
(3) forming ion injection windows so as to expose the surface of said protection film or said gate electrode on the channel regions of every memory cell by selectively etching at least said interlayer insulating film;
(4) forming a photoresist film having apertures which are selectively formed on said ion injection windows by a photolithographic method;
(5) forming an ion injected layer on desired channel regions by executing ion injection using said photoresist film and said interlayer insulating film.

6. A manufacturing method for a semiconductor memory device according to claim 5, wherein said protective layer is a silicon film or a silicon nitride film.

7. A manufacturing method for a semiconductor memory device according to claim 4, wherein the method further comprises, before forming said forming step (1) the step of:
forming a plurality of buried layers which cross said gate electrodes in the surface region of said silicon substrate.

8. A manufacturing method for a semiconductor memory device according to claim 4, wherein, the manufacturing method further comprises, after said forming step (5), the steps of:
filling the ion injection windows with an insulating film.

9. A manufacturing method for a semiconductor memory device according to claim 4, wherein the manufacturing method further comprises the step of:
forming a contact hole selectively exposing the surface of said silicon substrate simultaneously with the formation of ion injection windows.

10. A manufacturing method for a semiconductor memory device according to claim 9, wherein the manufacturing method comprises, after the formation step (5), the step of:
forming an insulating film side wall at the inner side surface of said contact hole at the same time as filling said ion injection window by depositing an insulating layer and etching back said insulating layer.

11. A manufacturing method for a semiconductor memory device according to claim 4, wherein etching in said step (3) is performed by use of said gate electrode as an etching stopper.

12. A manufacturing method for a semiconductor memory device according to claim 4, wherein the manufacturing method further comprises, after said step (3) and before said step (5), the step of covering said gate electrode with a protective film.
